(19) United States
(12) Patent Application Publication
(10) Pub. No.: US 2013/0056747 A1
(43) Pub. Date: Mar. 7, 2013

(54) NITRIDE SEMICONDUCTOR LIGHT EMITTING DEVICE AND MANUFACTURING METHOD THEREOF

(71) Applicants: Jin Sub LEE, Suwon (KR); Jung Sup Kim, Seoul (KR); Seong Suk Lee, Hwaseong (KR); Tae Young Park, Gwangju (KR); Cheol Soo Sone, Seoul (KR)

(72) Inventors: Jin Sub LEE, Suwon (KR); Jung Sup Kim, Seoul (KR); Seong Suk Lee, Hwaseong (KR); Tae Young Park, Gwangju (KR); Cheol Soo Sone, Seoul (KR)

(21) Appl. No.: 13/595,480

(22) Filed: Aug. 27, 2012

(30) Foreign Application Priority Data
Aug. 26, 2011 (KR) 10-2011-0085752

(51) Int. Cl. H01L 33/02

(52) U.S. Cl. 257/76; 438/47; 257/103; 257/E33.014

(57) ABSTRACT

A nitride semiconductor light emitting device and a manufacturing method thereof are provided. The nitride semiconductor light emitting device includes: forming a first conductivity-type nitride semiconductor layer on a substrate; forming an active layer on the first conductivity-type nitride semiconductor layer; and forming a second conductivity-type nitride semiconductor layer on the active layer. High output can be obtained by increasing doping efficiency in growing the conductivity type nitride semiconductor layer.

### CROSS-REFERENCE TO RELATED APPLICATIONS

This application claims the priority of Korean

Patent Application No. 10-2011-0085752 filed on Aug. 26, 2011, in the Korean Intellectual Property Office, the disclosure of which is incorporated herein by reference.

### BACKGROUND OF THE INVENTION

1. Field of the Invention

The present invention relates to a nitride semiconductor light emitting device and a manufacturing method thereof.

2. Description of the Related Art

A light emitting diode (LED) is a device including a material that emits light, in which energy generated through electron-hole recombination in semiconductor junction parts is converted into light to be emitted therefrom. LEDs are commonly employed as light sources in illumination devices, display devices, and the like, and the development of LEDs has thus been accelerated.

In particular, recently, the development and employment of gallium nitride-based LEDs has been increased, and mobile keypads, Turn signal light, camera flashes, and the like, using such a gallium nitride-based LED, have been commercialized, and in line with this, the development of general illumination devices using LEDs has accelerated. Like the products to which they are applied, such as a backlight unit of a large TV, a headlamp of a vehicle, a general illumination device, and the like, the purposes of LEDs are gradually moving from small portable products toward large-sized products having high output and high efficiency, and pertinent products need light sources that can support required characteristics thereof.

In order to enhance low light extraction efficiency of LEDs, silicon is doped in an AlGaN conductivity-type nitride semiconductor layer during the growth thereof in order to increase doping efficiency, but when a mole fraction of aluminum (Al) is increased, defects in the semiconductor layer are increased due to cation vacancy, carbon anti-site (C_{N}), dislocation, and the like. The increase in the semiconductor layer defects may reduce doping efficiency, making it difficult to manufacture high output semiconductor light emitting devices having high efficiency.

### SUMMARY OF THE INVENTION

An aspect of the present invention provides a nitride semiconductor light emitting device capable of a high output by increasing doping efficiency in growing a conductivity-type nitride semiconductor layer.

Another aspect of the present invention provides a method for manufacturing a nitride semiconductor light emitting device capable of a high output by increasing doping efficiency in growing a conductivity-type nitride semiconductor layer.

According to an aspect of the present invention, there is provided a method for manufacturing a nitride semiconductor light emitting device, including: forming a first conductivity-type nitride semiconductor layer on a substrate; forming an active layer on the first conductivity-type nitride semiconductor layer; and forming a second conductivity-type nitride semiconductor layer on the active layer, wherein in the forming of the first conductivity-type nitride semiconductor layer, indium having a certain concentration is repeatedly doped at certain intervals of time to form a plurality of indium doped layers in the first conductivity-type nitride semiconductor layer.

The method may further include: growing a buffer layer on the substrate before the forming of the first conductivity-type nitride semiconductor layer, and the buffer layer may be an AlN layer.

The first conductivity-type nitride semiconductor layer may include the indium doped layers and the silicon doped layers which are alternately laminated by doping silicon having a certain concentration between the indium doped layers.

The indium doped layers may be co-doped.

The first conductivity-type nitride semiconductor layer may be expressed by AlₓGa₍₁₋ₓ₎N (here, 0≦x≦1) and the first conductivity-type nitride semiconductor layer may be formed under an N₂ atmosphere at a temperature of 800° C.-900° C.

The indium doped layer of the first conductivity-type nitride semiconductor layer may be grown for two seconds, the indium doped layer may be grown for two seconds, and the silicon doped layer may be grown for four seconds.

The first conductivity-type nitride semiconductor layer may be formed through metal-organic chemical vapor deposition (MOCVD).

The substrate may be a sapphire substrate, SiC, Si, MgAl₂O₄, MgO, LiAlO₂, or LiGaO₂.

According to another aspect of the present invention, there is provided a nitride semiconductor light emitting device including: a first conductivity-type nitride semiconductor layer formed on a substrate and including alternately doped indium having a certain concentration and silicon having a certain concentration; an active layer formed on the first conductivity-type nitride semiconductor layer; and a second conductivity-type nitride semiconductor layer formed on the active layer.

The indium doped layer may be interposed between silicon doped layers in the first conductivity-type nitride semiconductor layer.

The first conductivity-type nitride semiconductor layer may be expressed by AlₓGa₍₁₋ₓ₎N (here, 0≦x≦1).

### BRIEF DESCRIPTION OF THE DRAWINGS

The above and other aspects, features and other advantages of the present invention will be more clearly understood from the following detailed description taken in conjunction with the accompanying drawings, in which:

FIGS. 1 through 4 are cross-sectional views illustrating respective processes of a method for manufacturing a nitride semiconductor light emitting device according to a first embodiment of the present invention;

FIG. 5 is a cross-sectional view illustrating a nitride semiconductor light emitting device according to a second embodiment of the present invention;

FIG. 6 is a graph showing growth conditions of a first conductivity-type nitride semiconductor layer according to the first embodiment of the present invention; and

FIG. 7 is a graph showing growth conditions of a first conductivity-type nitride semiconductor layer according to the second embodiment of the present invention.

### DETAILED DESCRIPTION OF THE PREFERRED EMBODIMENT

Embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

First, a nitride semiconductor light emitting device 100 according to a first embodiment of the present invention and a method for manufacturing the same will be described.

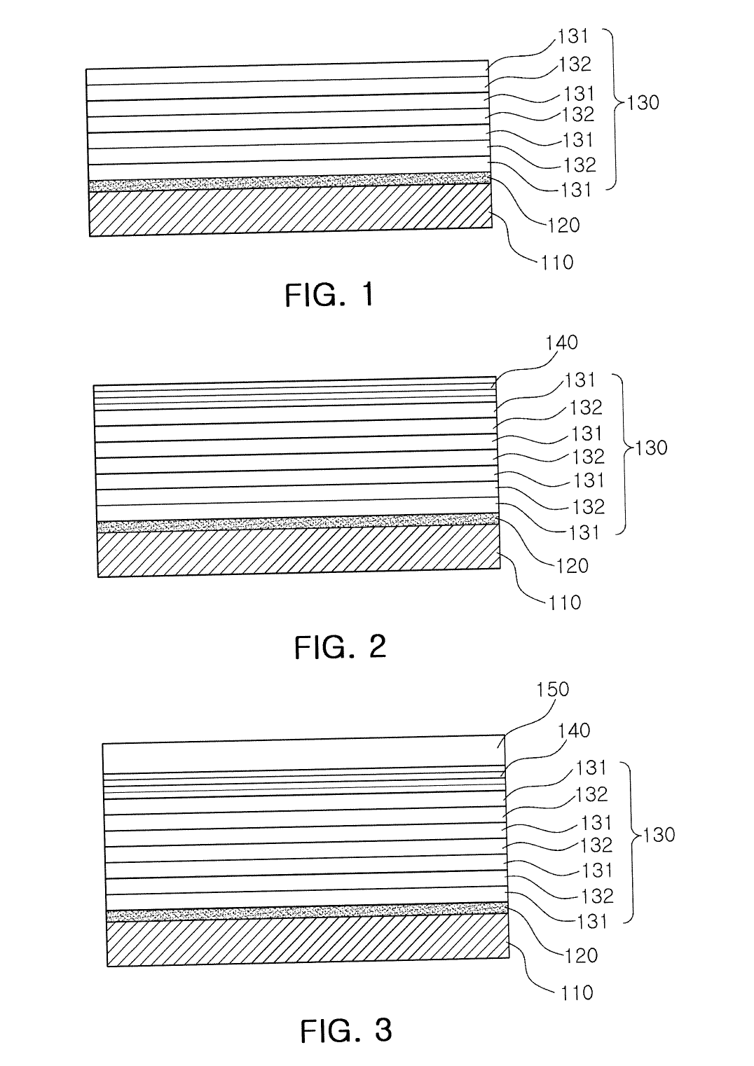

FIGS. 1 through 4 are cross-sectional views illustrating respective processes of a method for manufacturing a nitride semiconductor light emitting device according to a first embodiment of the present invention.

A method for manufacturing a nitride semiconductor layer 100 according to a first embodiment of the present invention includes forming a first conductivity-type nitride semiconductor layer 130 including a plurality of indium doped layers 131 on a substrate 110; forming an active layer 140 on the first conductivity-type nitride semiconductor layer 130; and forming a second conductivity-type nitride semiconductor layer 150 on the active layer 140.

First, as illustrated in FIG. 1, after the substrate 110 is prepared, the first conductivity-type nitride semiconductor layer 130 is formed on the substrate 110.

The substrate 110 may be any one of a sapphire substrate, a silicon carbide (SiC) substrate, a silicon (Si) substrate, MgAl₂O₄, MgO, LiAlO₂, and LiGaO₂, but the present invention is not limited thereto. In the present embodiment, a sapphire substrate may be used.

The first conductivity-type nitride semiconductor layer 130 is formed on the substrate 110. The first conductivity-type nitride semiconductor layer 130 may be made of a semiconductor material having a empirical formula AlₓGa₍₁₋ₓ₎N, and typically, AlGaN may be used. Here, the x value may be within a range of 0≦x≦1.

In the first conductivity-type nitride semiconductor layer 130, indium having a certain concentration is repeatedly doped to form a plurality of indium doped layers 131.

In general, when the first conductivity-type nitride semiconductor layer 130, an n-type layer, is formed of AlGaN, silicon (Si) is doped in growing AlGaN to enhance doping efficiency. However, when a mole fraction of aluminum (Al) is 50% or more, semiconductor layer defects are increased due to cation vacancy, carbon anti-site (CN), dislocation, and the like. The increase in semiconductor layer defects reduces doping efficiency, making it difficult to manufacture a high output semiconductor light emitting device having high efficiency.

In an embodiment of the present invention, in order to reduce semiconductor layer defects, indium is doped onto the first conductivity-type nitride semiconductor layer 130. Indium acts as an isoelectronic dopant during a process of growing the first conductivity-type nitride semiconductor layer 130, restraining cations of the semiconductor layer, further enhancing doping efficiency of the semiconductor layer. Thus, high output semiconductor light emitting device can be manufactured.

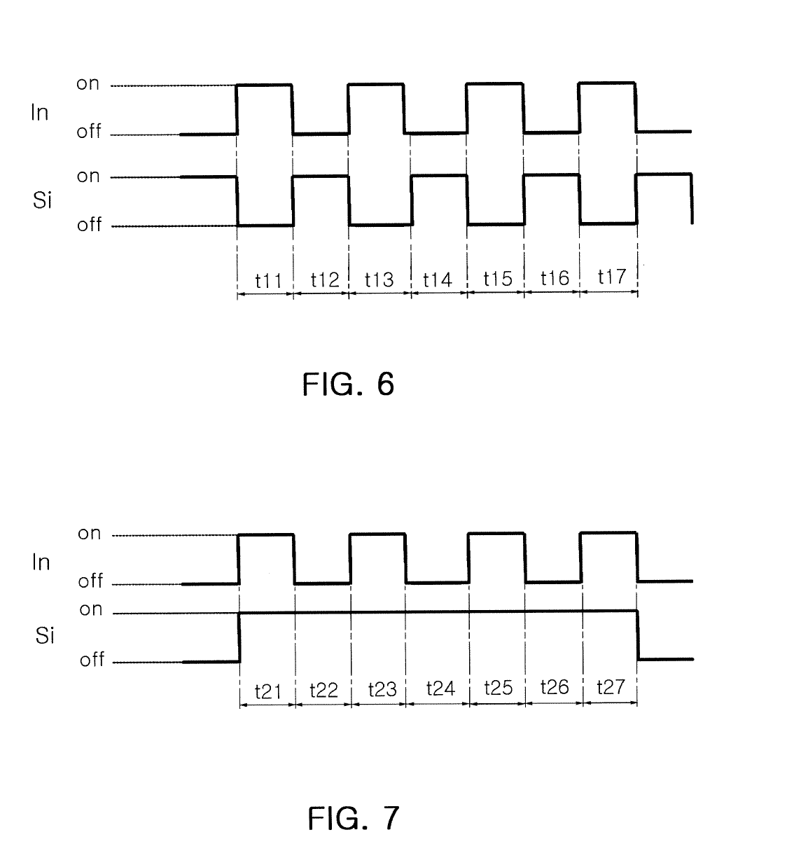

FIG. 6 is a graph showing growth conditions of the first conductivity-type nitride semiconductor layer 130 according to the first embodiment of the present invention. As can be seen in FIG. 6, indium and silicon are alternately doped through pulse doping so as to be grown, and the first conductivity-type nitride semiconductor layer 130 grown through pulse doping has a multilayer structure in which indium and silicon are alternately doped. Stress may act on the first conductivity-type nitride semiconductor layer 130 due to thickly doped silicon, thereby causing cracks. However, when the first conductivity-type nitride semiconductor layer 130 is co-doped with silicon and indium, cracks may not be generated in the semiconductor layer.

Here, the intervals of time durations t11, t13, t15, and t17 during which indium is grown are uniform, and may be, for example, about 2 seconds. Also, intervals of time durations t12, t14, and t16 during which silicon is grown are also uniform and may be, for example, about 4 seconds.

In detail, the first conductivity-type nitride semiconductor layer 130 may be grown at a growth temperature ranging at a temperature from 800□ to 900□ under an N₂ atmosphere through metal-organic chemical vapor deposition (MOCVD), and as shown in FIG. 6, the indium doped layers 131 may be grown for two seconds and silicon doped layers 132 may be formed for four seconds. An upper limit of the number of the alternately stacked indium doped layers 131 and silicon doped layers 132 is not limited and the number of stacked doped layers may be increased, according to the characteristics of the semiconductor light emitting device desired to be manufactured. Also, the indium doped layers 131 grown for two seconds may be formed to be 0.3%˜1% of the first conductivity-type nitride semiconductor layer 130.

Also, before the formation of the first conductivity-type nitride semiconductor layer 130, a buffer layer 120 may be further formed on the substrate 110. The buffer layer 120 serves to reduce a lattice mismatch between the substrate 110 and the first conductivity-type nitride semiconductor layer 130, and in the present embodiment, AlN is used to form a material of the buffer layer 120.

Next, as illustrated in FIG. 2, the active layer 140 is formed on the first conductivity-type nitride semiconductor layer 130.

The active layer 140 may have multi-quantum well structure in which quantum well layers and quantum barrier layers are alternately laminated. For example, the active layer 140 may have an MQW structure in which quantum barrier layers and quantum well layers of AlₓIn_{y}Ga_{1-x-y}N (0≦x≦1, 0≦y≦1, 0≦x+y≦1) are alternately laminated to have a certain band gap, and as electrons and holes are recombined according to the quantum wells, light is emitted. The active layer 140 may be a layer for emitting deep ultraviolet light (having a wavelength range of 190 nm□369 nm), and may be grown through MOCVD like the first conductivity-type nitride semiconductor layer 130 is.

Thereafter, as illustrated in FIG. 3, the second conductivity-type nitride semiconductor layer 150 is formed on the active layer 140.

The second conductivity-type nitride semiconductor layer 150 may be made of a p-type impurity-doped semiconductive material having the same empirical formula AlₓGa₍₁₋ₓ₎N as that of the first conductivity-type nitride semiconductor layer 130. Here, the x value may be within a range of 0≦x≦1. Also, magnesium (Mg), zinc (Zn), beryllium (Be), or the like, may be used as the p-type impurity. In the present embodiment, p-AlGaN may be used as a material of the second conductivity-type nitride semiconductor layer 150.

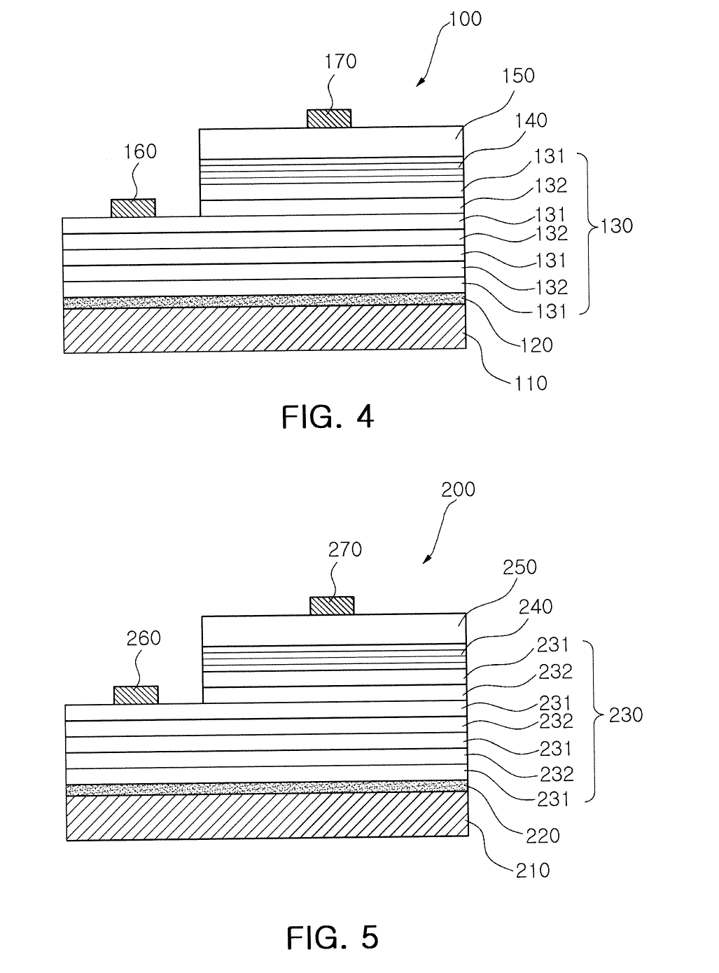

Thereafter, as illustrated in FIG. 4, mesa-etching is performed to expose a portion of the first conductivity-type nitride semiconductor layer 130, and first and second electrodes 160 and 170 are in respective regions of the first and second conductivity-type nitride semiconductor layers 130 and 150, thus completing a nitride semiconductor light emitting device 100 according to an embodiment of the present invention.

The first and second electrodes 160 and 170 may be formed as a single layer or multiple layers made of a material selected from the group consisting of nickel (Ni), gold (Au), silver (Ag), titanium (Ti), chromium (Cr), and copper (Cu). The first and second electrodes 160 and 170 may be formed through a known deposition method such as a chemical vapor deposition (CVD) method or electron beam evaporation, or a process such as sputtering, or the like.

The nitride semiconductor light emitting device 100 according to the first embodiment of the present invention manufactured by the foregoing manufacturing method includes the first conductivity-type nitride semiconductor layer 130 in which indium having a certain concentration and silicon having a certain concentration are alternately doped, the active layer 140 formed on the first conductivity-type nitride semiconductor layer 130, and the second conductivity-type nitride semiconductor layer 150 formed on the active layer 140.

In the nitride semiconductor light emitting device 100 having the foregoing configuration, since the indium doped layers 131 and the silicon doped layers 132 are alternately laminated in the first conductivity-type nitride semiconductor layer 130, as described above, indium acts as an isoelectronic dopant to restrain a cation defect of the semiconductor layer, thus further enhancing doping efficiency of the semiconductor layer.

A nitride semiconductor light emitting device 200 and a manufacturing method thereof according to a second embodiment of the present invention will hereinafter be described.

The nitride semiconductor light emitting device 200 according to the second embodiment of the present invention is manufactured through a similar process to that of the nitride semiconductor light emitting device 100 according to the first embodiment of the present invention, but, unlike the first embodiment as described above, in the second embodiment of the present invention, silicon is co-doped with indium in forming the first conductivity-type nitride semiconductor layer 130.

First, like the first embodiment as described above, after a substrate 210 is prepared, the first conductivity-type nitride semiconductor layer 230 is formed on the substrate 110. The first conductivity-type nitride semiconductor layer 230 may be made of a semiconductor material having a empirical formula AlₓGa₍₁₋ₓ₎N, and typically, AlGaN may be used. Here, the x value may be within a range of 0≦x≦1.

FIG. 7 is a graph showing growth conditions of the first conductivity-type nitride semiconductor layer 230 according to the second embodiment of the present invention. As can be seen in FIG. 7, indium and silicon are alternately doped through delta doping so as to be grown, and the first conductivity-type nitride semiconductor layer 230 grown through delta doping has a multilayer structure in which the silicon and indium-codoped layer and a silicon-only doped layer are laminated.

Here, the intervals of time durations t21, t23, t25, and t27 in which indium is grown are uniform, which may be, for example, about 2 seconds. Also, intervals of time durations t12, t14, and t16 in which silicon is grown are also uniform and may be, for example, about 4 seconds.

In this manner, in the forming of the first conductivity-type nitride semiconductor layer 230, when silicon is co-doped when indium is doped, indium together with silicon acts as a dopant, to reduce a degradation of a band gap of the first conductivity-type nitride semiconductor layer 230.

Also, before the formation of the first conductivity-type nitride semiconductor layer 230, a buffer layer 220 may be further formed on the substrate 210. The buffer layer 220 serves to reduce a lattice mismatch between the substrate 210 and the first conductivity-type nitride semiconductor layer 230, and in the present embodiment, AlN is used to form a material of the buffer layer 220

Next, like the first embodiment as described above, the active layer 240 is formed on the first conductivity-type nitride semiconductor layer 230.

The active layer 240 may have multi-quantum well structure in which quantum well layers and quantum barrier layers are alternately laminated. For example, the active layer 240 may have an MQW structure in which quantum barrier layers and quantum well layers of AlₓIn_{y}Ga_{1-x-y}N (0≦x≦1, 0≦y≦1, 0≦x+y≦1) are alternately laminated to have a certain band gap. As electrons and holes are recombined according to the quantum well layers, light is emitted. The active layer 240 may be a layer for emitting deep ultraviolet ray (having a wavelength range of 190 nm□369 nM), and may be grown through MOCVD like the first conductivity-type nitride semiconductor layer 230 does.

Thereafter, like the first embodiment as described above, the second conductivity-type nitride semiconductor layer 250 is formed on the active layer 240.

The second conductivity-type nitride semiconductor layer 250 may be made of a p-type impurity-doped semiconductive material having the same empirical formula AlₓGa₍₁₋ₓ₎N as that of the first conductivity-type nitride semiconductor layer 230. Here, the x value may be within a range of 0≦x≦1. Also, magnesium (Mg), zinc (Zn), beryllium (Be), or the like, may be used as the p-type impurity. In the present embodiment, p-AlGaN may be used as a material of the second conductivity-type nitride semiconductor layer 250.

Thereafter, like the first embodiment as described above, mesa-etching is performed to expose a portion of the first conductivity-type nitride semiconductor layer 230, and first and second electrodes 260 and 270 are formed on one region of each of the first and second conductivity-type nitride semiconductor layers 230 and 250, thus completing a nitride semiconductor light emitting device 200 according to an embodiment of the present invention. Here, the first and second electrodes 260 and 270 may be formed as a single layer or multiple layers made of a material selected from the group consisting of nickel (Ni), gold (Au), silver (Ag), titanium (Ti), chromium (Cr), and copper (Cu). The first and second electrodes 160 and 170 may be formed through a known deposition method such as a chemical vapor deposition (CVD) method, an electron beam evaporation method, or a process such as sputtering, or the like.

The nitride semiconductor light emitting device 200 according to the second embodiment of the present invention manufactured by the foregoing manufacturing method includes the first conductivity-type nitride semiconductor layer 230 in which silicon-doped layers 232 and the silicon-indium co-doped layers 231 are alternately laminated, the active layer 240 formed on the first conductivity-type nitride semiconductor layer 230, and the second conductivity-type nitride semiconductor layer 250 formed on the active layer 240.

In the nitride semiconductor light emitting device 200 having the foregoing configuration, since the indium doped layer 131 is co-doped with silicon in the first conductivity-type nitride semiconductor layer 230, indium together with silicon acts as a dopant, reducing a degradation of a band gap of the first conductivity-type nitride semiconductor layer 230.

As set forth above, according to embodiments of the invention, a nitride semiconductor light emitting device capable of performing a high output by increasing doping efficiency in growing a conductivity-type nitride semiconductor layer, and a manufacturing method thereof can be provided.

While the present invention has been shown and described in connection with the embodiments, it will be apparent to those skilled in the art that modifications and variations can be made without departing from the spirit and scope of the invention as defined by the appended claims.

What is claimed is:

1. A method for manufacturing a nitride semiconductor light emitting device, the method comprising:
forming a first conductivity-type nitride semiconductor layer on a substrate;
forming an active layer on the first conductivity-type nitride semiconductor layer; and
forming a second conductivity-type nitride semiconductor layer on the active layer,
wherein in the forming of the first conductivity-type nitride semiconductor layer, indium having a certain concentration is repeatedly doped at certain intervals of time to form a plurality of indium doped layers in the first conductivity-type nitride semiconductor layer.

2. The method of claim 1, further comprising growing a buffer layer on the substrate before the forming of the first conductivity-type nitride semiconductor layer.

3. The method of claim 2, wherein the buffer layer is an AlN layer.

4. The method of claim 1, wherein the first conductivity-type nitride semiconductor layer includes the indium doped layers and the silicon doped layers which are alternately laminated by doping silicon having a certain concentration between the indium doped layers.

5. The method of claim 4, wherein the indium doped layers are co-doped.

6. The method of claim 1, wherein the first conductivity-type nitride semiconductor layer is expressed by AlₓGa₍₁₋ₓ₎N (here, 0≦x≦1).

7. The method of claim 4, wherein the first conductivity-type nitride semiconductor layer is formed under an N₂ atmosphere at a temperature of 800° C.-900° C.

8. The method of claim 7, wherein the indium doped layer of the first conductivity-type nitride semiconductor layer is grown for two seconds.

9. The method of claim 4, wherein the indium doped layer is grown for two seconds, and the silicon doped layer is grown for four seconds.

10. The method of claim 1, wherein the first conductivity-type nitride semiconductor layer is formed through metal-organic chemical vapor deposition (MOCVD).

11. The method of claim 1, wherein the substrate is a sapphire substrate, SiC, Si, MgAl₂O₄, MgO, LiAlO₂, or LiGaO₂.

12. A nitride semiconductor light emitting device comprising:
a first conductivity-type nitride semiconductor layer formed on a substrate and including alternately doped indium having a certain concentration and silicon having a certain concentration;
an active layer formed on the first conductivity-type nitride semiconductor layer; and
a second conductivity-type nitride semiconductor layer formed on the active layer.

13. The nitride semiconductor light emitting device of claim 12, wherein the indium doped layer is interposed between silicon doped layers in the first conductivity-type nitride semiconductor layer.

14. The nitride semiconductor light emitting device of claim 12, wherein the first conductivity-type nitride semiconductor layer is expressed by AlₓGa₍₁₋ₓ₎N (here, 0≦x≦1).
